(19) United States
(12) Patent Application Publication
(10) Pub. No.: US 2009/0165722 A1
(43) Pub. Date: Jul. 2, 2009

(54) APPARATUS FOR TREATING SUBSTRATE

(75) Inventor: Heon-Sik HA, Gyeonggi-do (KR)

Correspondence Address: HOSOON LEE, 9600 SW OAK ST. SUITE 525, TIGARD, OR, 97223, US

(73) Assignee: JUSUNG ENGINEERING CO., LTD, Gyeonggi-do (KR)

(21) Appl. No.: 12/340,669

(22) Filed: Dec. 20, 2008

(30) Foreign Application Priority Data
Dec. 26, 2007 (KR) 10-2007-0137630

(51) Int. Cl. C23C 16/455

(52) U.S. Cl. 118/728

(57) ABSTRACT

An apparatus for treating a substrate includes: a chamber including an upper lid; a rear plate in the chamber; a gas distributing plate under the rear plate, the gas distributing plate including a plurality of injection holes, the gas distributing plate combined with the upper lid using a plurality of first coupling means; and a substrate holder under the gas distributing plate, the substrate holder having the substrate thereon.

This application claims the benefit of Korean Patent Application No. 2007-0137630, filed on Dec. 26. 2008, which is hereby incorporated by a reference in its entirety.

### TECHNICAL FIELD

The present invention relates to an apparatus for treating a substrate, and more particularly to an apparatus including a gas distributing plate.

### BACKGROUND

In general, a large-sized glass substrate is used for a fabrication process for a semiconductor device such as a flat panel display (FPD) device and a solar cell. The fabrication process for a semiconductor device includes repetition of a deposition step of a thin film, a photolithographic step for a photoresist (PR) pattern and an etch step of the thin film for a thin film pattern. Each step of the fabrication process for a semiconductor device may be performed in an apparatus for treating a substrate. For example, the deposition step and the etch step of the fabrication process for a FPD device and a solar cell may be performed in a process chamber into which reaction materials in a gas phase are injected downstream from a top portion thereof. As a result, the process chamber may include a gas distributing plate having a plurality of injection holes over the substrate for a uniform distribution of the reaction gases.

Specifically, a plasma enhanced chemical vapor deposition (PECVD) method where a chemical reaction between reaction gases excited to a plasma by an external high voltage energy is induced has been widely used. As a size of the substrate increases, a size of the gas distributing plate increases. As a result, the large-sized gas distributing plate may be warped due to a thermal expansion in the process chamber.

process chamber 12, a rear plate 14, a gas inlet 36, a gas distributing plate 18, a substrate holder 22, a gas outlet 24, a matcher 32 and a radio frequency (RF) power supply 30. The rear plate 14 is disposed at an upper portion of the process chamber 12 and is used as a first plasma electrode. The gas inlet 36 is connected to the rear plate 14 and supplies reaction gases to the process chamber 12. The gas distributing plate 18 is disposed under the rear plate 14 and includes a plurality of injection holes 16. The gas distributing plate 18 may be formed of aluminum (Al). The substrate holder 22 having a substrate 20 thereon is used as a second plasma electrode. The used reaction gases and a residual product in the process chamber 12 are exhausted through the gas outlet 24. In addition, the RF power supply 30 is connected to and supplies a source power to the rear plate through the matcher 32 for minimizing impedance.

The gas distributing plate 18 is spaced apart from the rear plate 14 to define a buffer space 26. The gas distributing plate 18 is fixed to or supported by a supporter 28 extending from the rear plate 14. In addition, to prevent a thermal deformation such as a warpage of the gas distributing plate 18 at a central portion thereof due to a thermal expansion, the gas distributing plate 18 is combined with the rear plate 14 by a bolt 34. As a result, the distance between the gas distributing plate 18 and the substrate holder 22 is kept constant by suppressing the thermal deformation of the gas distributing plate 18 due to a thermal expansion.

However, the rear plate 14 may be deformed due to a pressure difference when a reaction space defined by the rear plate 14 and lower portion of the process chamber 12 is evacuated. For example, when the reaction space of the process chamber 12 is evacuated to have a vacuum condition, a central portion of the rear plate 14 as a mass center may be downwardly warped. Since the gas distributing plate 18 is combined with the rear plate 14 by the bolt 34, the gas distributing plate 18 is also warped. Accordingly, the distance between the gas distributing plate 18 and the substrate holder 22 may varied according to positions. As a result, a thin film on the substrate 20 has a non-uniformity in thickness or a thin film pattern on the substrate 20 has a non-uniformity in etch profile.

### SUMMARY

Accordingly, the present invention is directed to an apparatus for treating a substrate e that substantially obviate one or more of the problems due to limitations and disadvantages of the related art.

An object of the present invention is to provide an apparatus for treating a substrate where deformation of a gas distributing plate is prevented.

An apparatus for treating a substrate includes: a chamber including an upper lid; a rear plate in the chamber; a gas distributing plate under the rear plate, the gas distributing plate including a plurality of injection holes, the gas distributing plate combined with the upper lid using a plurality of first coupling means; and a substrate holder under the gas distributing plate, the substrate holder having the substrate thereon.

### BRIEF DESCRIPTION OF THE DRAWINGS

The accompanying drawings, which are included to provide a further understanding of the invention and are incorporated in and constitute a part of this specification, illustrate embodiments of the invention.

FIG. 1 is a cross-sectional view showing an apparatus for treating a substrate according to the related art;

FIG. 2 is a cross-sectional view showing an apparatus for treating a substrate according to an embodiment of the present invention;

FIG. 3 is a magnified view corresponding to a portion A of FIG. 2;

FIG. 4 is a plan view corresponding to a portion A of FIG. 2;

FIG. 5 is a plan view showing an apparatus for treating a substrate according to another embodiment of the present invention;

FIG. 6 is a cross-sectional view showing a coupling means of an apparatus for treating a substrate according to another embodiment of the present invention; and

FIG. 7 is a magnified view showing a portion B of FIG. 6.

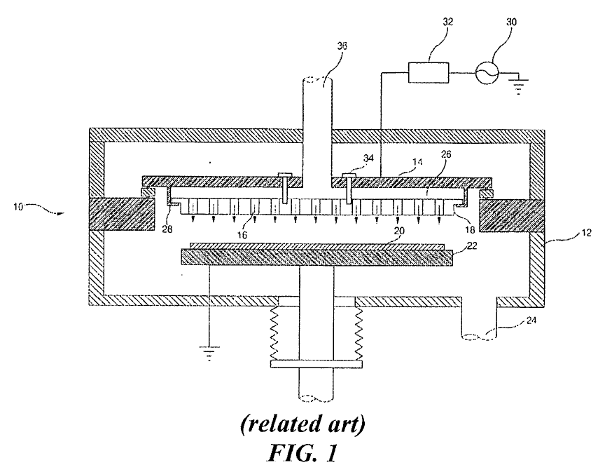

### DETAILED DESCRIPTION OF THE PREFERRED EMBODIMENTS

Reference will now be made in detail to embodiments which are illustrated in the accompanying drawings. Wherever possible, similar reference numbers will be used to refer to the same or similar parts.

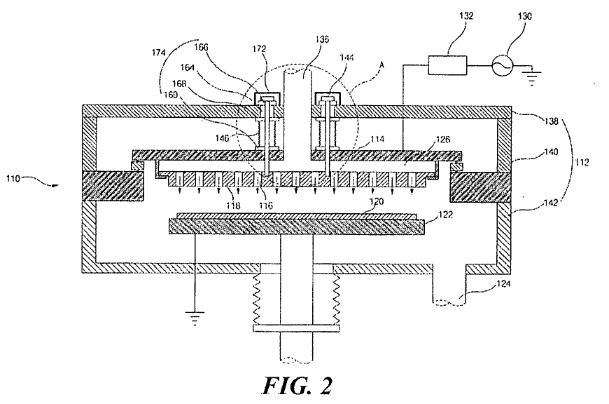

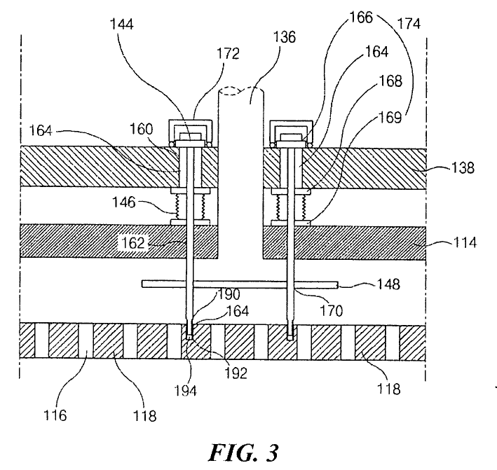

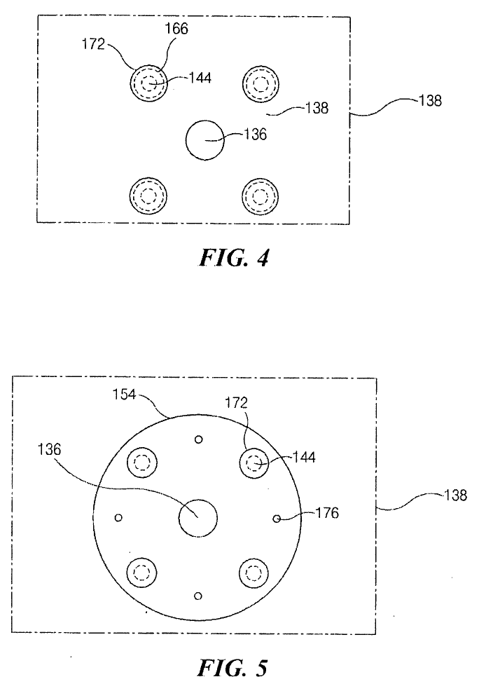

FIG. 2 is a cross-sectional view showing an apparatus for treating a substrate according to an embodiment of the present invention, and FIGS. 3 and 4 are a magnified view and a plan view, respectively, corresponding to a portion A of FIG. 2.

In FIGS. 2, 3 and 4, an apparatus 110 for treating a substrate includes a process chamber 112, a rear plate 114, a gas inlet 136, a gas distributing plate 118, a substrate holder 122, a gas outlet 124, a matcher 132 and a radio frequency (RF) power supply 130. The rear plate 114 is disposed at an upper portion of the process chamber 112 and is used as a first plasma electrode. The gas inlet 136 is connected to the rear plate 114 and supplies reaction gases to the process chamber 112. The gas distributing plate 118 is disposed under the rear plate 114 and includes a plurality of injection holes 116. The gas distributing plate 118 may be formed of aluminum (Al). The substrate holder 122 having a substrate 120 thereon is used as a second plasma electrode. The used reaction gases and a residual product in the process chamber 112 are exhausted through the gas outlet 124. In addition, the RF power supply 130 is connected to and supplies a source power to the rear plate through the matcher 132 for minimizing impedance.

The process chamber 112 includes an upper lid 138, a side lid 140 and a chamber body 142. The upper lid 138, the side lid 140 and the chamber body 142 are combined with each other by a sealing means such as an O-ring. The upper lid 138 is spaced apart from the rear plate 114, and the gas distributing plate 118 is spaced apart from the rear plate 114. In addition, the gas distributing plate 118 is fixed to or supported by a supporter 128 extending from the rear plate 114. As a result, a boundary portion of the gas distribution plate 118 is combined with a boundary portion of the rear plate 114 and a central portion of the gas distribution plate 118 is spaced apart from a central portion of the rear plate 114 to define a buffer space 126. Further, a reaction space including the buffet space 126 is defined by the rear plate 114 and the chamber body 142. Before the substrate 120 is treated with the reaction gases, the reaction space where the substrate 120 is disposed is evacuated to have a pressure lower than the exterior including a space defined by the rear plate 114, the upper lid 138 and the side lid 140.

To prevent a thermal deformation such as a warpage of the gas distributing plate 118 at a central portion thereof due to a thermal expansion during a process of treating the substrate 120, the gas distributing plate 118 is combined with the upper lid 138 by a plurality of first coupling means including a plurality of first screws 144 and a plurality of screw holes 164. As a result, the distance between the gas distributing plate 118 and the substrate holder 122 is kept constant by suppressing the deformation of the gas distributing plate 118 due to a thermal expansion. In addition, the distance between the gas distributing plate 118 and the substrate holder 122 is kept constant regardless of the deformation of the rear plate 114 due to a pressure difference when a reaction space is evacuated. Accordingly, a thin film formed on the substrate 120 through a deposition process has a uniform thickness, or a thin film pattern formed on the substrate 120 through an etch process has a uniform profile.

The upper lid 138 includes a plurality of first through holes 160 and the rear plate 114 includes a plurality of second through holes 162 for combining the gas distributing plate 118 and the upper lid 138. In addition, the gas distributing plate 118 includes the plurality of screw holes 164. A first screw thread 190 is formed on an outer surface of a lower portion of each of the plurality of first screws 144 and a second screw thread 192 is formed on an inner surface of each of the plurality of screw holes 164. The plurality of first screws 144 pass through the plurality of first through holes 160 and the plurality of second through holes 162 and are combined with the plurality of screw holes 164. Accordingly, the plurality of screw holes 164 may not penetrate the gas distributing plate 118. Each of the plurality of first screws 144 may not contact a bottom of each of the plurality of'screw holes 164 to define a buffer region 194. Accordingly, a distance between the upper lid 138 and the gas distributing plate 118 may be controlled by a coupling degree (i.e., coupling depth) of the plurality of first screws 144 and the plurality of screw holes 164.

To prevent injection of external air through the plurality of first through holes 160 in the upper lid 138, a screw cap 172 is formed over each of the plurality of first screws 144 and a sealing means such as an O-ring is disposed between the screw cap 172 and the upper lid 138 for hermetic sealing. Further, to keep airtight even when the distance between the upper lid 138 and the rear plate 114 varies, an expansible bellows 146 surrounding each of the plurality of first screws 144 is formed between the upper lid 138 and the rear plate 114. As a result, while the substrate 120 is treated, a vacuum state of the reaction space defined by the rear plate 114 and the chamber body 142 is kept by the screw cap 172 and the bellows 146 regardless of the pressure of the space surrounded by the rear plate 114, the upper lid 138 and the side lid 140.

The plurality of first screws 144 may be formed of a metallic material. Since an RF power is supplied to the rear plate 114 by the RF power supply 130, a plurality of insulting means 174 are formed for each of the plurality of first screws 144 to prevent an electrical connection of the rear plate 114 and the upper lid 138. The plurality of insulating means 174 may include first, second, third and fourth insulating means 164, 166, 168 and 169. To prevent an electrical connection between each screw 144 and the upper lid 138, the first insulating means 164 is formed in each of the plurality of first through holes 160, and the second insulating means 166 is formed between an upper portion of each screw 144 and a front surface of the tipper lid 138. In addition, the third insulating means 168 is formed between a rear surface of the upper lid 138 and the bellows 146 to prevent an electrical connection between the bellows 146 arid the tipper lid 138. Further, the fourth insulating means 169 is formed between the bellows 146 and a front surface of the rear plate 114 to prevent an electrical connection between the bellows 146 and the rear plate 114. The plurality of screws 144 may be disposed at a central portion of the upper lid 138 to surround the gas inlet 136.

The apparatus 110 may further include a baffle 148 in the buffer space 126 defined by the rear plate 114 and the gas distributing plate 118 to improve diffusion of the reaction gas from the gas inlet 136. The baffle 148 may include a plurality of third through holes 170 for the plurality of first screws 144.

FIG. 5 is a plan view showing an apparatus for treating a substrate according to another embodiment of the present invention.

In FIG. 5, a fifth insulating means 154 instead of the plurality of second insulting means 166 of FIG. 4 is formed between an upper portion of each screw 144 and a front surface of a upper lid 138. Hie fifth insulating means 154 may have a circular plate shape having an opening for a gas inlet 136. In addition, the fifth insulating means 154 may be combined with the upper lid 138 using a plurality of second coupling means such as a plurality of second screws 176.

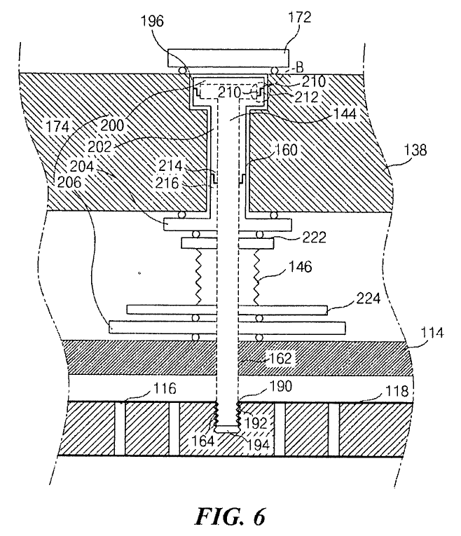

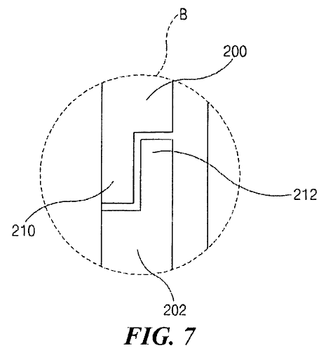

FIG. 6 is a cross-sectional view showing a coupling means of an apparatus for treating a substrate according to another embodiment of the present invention, and FIG. 7 is a magnified view showing a portion B of FIG. 6.

In FIGS. 6 and 7, an apparatus for treating a substrate includes a rear plate 114 and a gas distributing plate 118. Although not shown in FIGS. 6 and 7, the apparatus further includes a process chamber, a gas inlet, a substrate holder, a gas outlet, a matcher and a radio frequency (RF) power supply. The process chamber includes an upper lid 138, a side lid (not shown) and a chamber body (not shown). The upper lid 138 is spaced apart from the rear plate 114, and the gas distributing plate 118 is spaced apart from the rear plate 114.

To prevent a thermal deformation such as a warpage of the gas distributing plate 118 at a central portion thereof due to a thermal expansion during a process of treating a substrate, the gas distributing plate 118 is combined with the upper lid 138 by a plurality of first coupling means including a plurality of first screws 144 and a plurality of screw holes 164. As a result, the distance between the gas distributing plate 118 and the substrate holder is kept constant by suppressing the deformation of the gas distributing plate 118 due to a thermal expansion. In addition, the distance between the gas distributing plate 118 and the substrate holder 122 is kept constant regardless of the deformation of the rear plate 114 due to a pressure difference when a reaction space is evacuated. Accordingly, a thin film formed on the substrate through a deposition process has a uniform thickness, or a thin film pattern formed on the substrate through an etch process has a uniform profile.

The upper lid 138 includes a plurality of first through holes 160 and the rear plate 114 includes a plurality of second through holes 162 for combining the gas distributing plate 118 and the upper lid 138. In addition, the gas distributing plate 118 includes the plurality of screw holes 164. A first screw thread 190 is formed on an outer surface of a lower portion of each of the plurality of first screws 144 and a second screw thread 192 is formed on an inner surface of each of the plurality of screw holes 164. The plurality of first screws 144 pass through the plurality of first through holes 160 and the plurality of second through holes 162 and are combined with the plurality of screw holes 164, respectively. Accordingly, the plurality of screw holes 164 may not penetrate the gas distributing plate 118. Each of the plurality of first screws 144 may not contact a bottom of each of the plurality of screw holes 164 to define a buffer region 194. Accordingly, a distance between the upper lid 138 and the gas distributing plate 118 may be controlled by a coupling degree (i.e., coupling depth) of the plurality of first screws 144 and the plurality of screw holes 164.

The upper lid 138 further includes a plurality of insertion holes 196 into which upper portions of the plurality of first screws 144 are inserted such that the upper portions, i.e., heads, of the plurality of first screws 144 form a flat surface with the upper lid 138 without protrusion.

To prevent injection of external air through the plurality of first through holes 160 in the upper lid 138, a screw cap 172 having a plate shape is formed over each of the plurality of first screws 144 and a sealing means such as an O-ring is disposed between the screw cap 172 and the upper lid 138 for hermetic sealing. Further, to keep airtight even when the distance between the upper lid 138 and the rear plate 114 varies, an expansible bellows 146 surrounding each of the plurality of first screws 144 is formed between the upper lid 138 and the rear plate 114. In addition, a first flange 221 is formed between the upper lid 138 and the bellows 146 and a second flange 224 is formed between the bellows 146 and the rear plate 114 using a sealing means such as an O-ring. As a result, while the substrate is treated, a vacuum state of the reaction space defined by the rear plate 114 and the chamber body is kept by the screw cap 172 and the bellows 146 regardless of the pressure of the space between the rear plate 114 and the upper lid 138.

The plurality of first screws 144 may be formed of a metallic material. Since an RF power is supplied to the rear plate 114 by the RF power supply, a plurality of insulting means 174 are formed for each of the plurality of first screws 144 to prevent an electrical connection of the rear plate 114 and the upper lid 138. The plurality of insulating means 174 may include first, second, third and fourth insulating means 200, 202, 204 and 206. To prevent an electrical connection between each screw 144 and the upper lid 138, the first insulating means 200 is formed oil the upper portion of each first screw 144 in each insertion hole 196, and the second insulating means 202 is formed in an upper portion of each first through hole 160 to surround each screw 144.

In addition, the third insulating means 204 is formed in a lower portion of each first through hole 160 to surround each screw 144 and is formed between the upper lid 138 and the first flange 222. Accordingly, an electrical connection between each first screw 144 and the upper lid 138 as well as an electrical connection between the bellows 146 and the upper lid 138 are prevented by the third insulating means 204. Further, the fourth insulating means 206 is formed between the second flange 224 and the rear plate 114 to prevent an electrical connection between the bellows 146 and the rear plate 114. In another embodiment, the plurality of insulating means 174 may further include a fifth insulating means in the bellows 146 to prevent an electrical connection between each first screw 144 and the bellows 146. The first flange 222 and the third insulating means 204 may be combined with a sealing means such as an O-ring, and the second flange 224 and the fourth insulating means 206 may be combined with a sealing means such as an O-ring.

The first insulating means 200 includes a first step portion 210 at a lower circumference portion thereof. In addition, the second insulating means 202 includes a second step portion 212 at an upper circumference portion thereof and a third step portion 214 at a lower circumference portion thereof. Furthermore, the third insulating means 204 includes a fourth step portion 216 at an upper circumference portion thereof. The first and second step portions 210 and 212 have shapes corresponding to each other such that the first step portion 210 is inserted into the second step portion 212. Similarly, the third and fourth step portions 214 and 216 have shapes corresponding to each other such that the third step portion 214 is inserted into the fourth step portion 216. As a result, the first and second insulating means 200 and 202 are combined with each other and the second and third 202 and 204 are combined with each other. After each first screw 144 is combined with the gas distributing plate 118 through the second and third insulating means 202 and 204 in each first through hole 160, the first insulating means 200 may be combined with the upper lid 138.

Consequently, in an apparatus for treating a substrate according to an embodiment of the present invention, since a central portion of a gas distributing plate is combined with an upper lid of a process chamber through a rear plate, deformation of the gas distributing plate due to a thermal expansion is prevented. In addition, since a space between the upper lid and the rear plate has a pressure higher than a pressure of a reaction space having the substrate, the upper lid does not experience a pressure difference. As a result, deformation of the gas distributing plate according to deformation of the rear plate due to a pressure difference is prevented. Accordingly, a distance between the gas distributing plate and the substrate is kept constant and uniformity in treatment of the substrate such as deposition and etching of the apparatus is improved.

It will be apparent to those skilled in the art that various modifications and variations can be made in an apparatus for treating a substrate of the present invention without departing from the spirit or scope of the invention. Thus, it is intended that the present invention cover the modifications and variations of this invention provided they come within the scope of the appended claims and their equivalents.

What is claimed is:

1. An apparatus for treating a substrate, comprising:
a chamber including all upper lid;
a rear plate in the chamber;
a gas distributing plate under the rear plate, the gas distributing plate including a plurality of in section holes, the gas distributing plate combined with the upper lid using a plurality of first coupling means: and
a substrate holder under the gas distributing plate, the substrate holder having the substrate thereon.

2. The apparatus according to claim 1, wherein a radio frequency power is applied to the rear plate and the substrate holder such that a plasma is generated in the chamber.

3. The apparatus according to claim 1, wherein the plurality of first coupling means include a plurality of first screws and a plurality of screw holes in the gas distributing plate.

4. The apparatus according to claim 3 wherein the upper lid includes a plurality of first through holes and the rear plate includes a plurality of second through holes, and wherein the plurality of first screws are combined with the plurality of screw holes through the plurality of first through holes and the plurality of second through holes.

5. The apparatus according to claim 4, further comprising a screw cap over each of the plurality of first screws and a bellows between the upper lid and the rear plate for hermetic sealing, wherein the bellows surrounds each of the plurality of first screws.

6. The apparatus according to claim 5, further comprising First, second, third and fourth insulating means for insulating the upper lid from the gas distributing plate, wherein the first insulating means is formed in each of the plurality of first through holes, the second insulating means is formed between each of the plurality of first screws and a front surface of the upper lid, the third insulating means is formed between a rear surface of the upper lid and the bellows, and the fourth insulating means is formed between the bellows and the rear plate.

7. The apparatus according to claim 6, wherein the second insulating means has a circular plate shape having an opening and is combined with the upper lid using a plurality of second coupling means.

8. The apparatus according to claim 5, wherein the upper lid includes a plurality of insertion holes and upper portions of the plurality of first screws are inserted into the plurality of insertion holes.

9. The apparatus according to claim 8, further comprising a first flange between the upper lid and the bellows and a second flange between the bellows and the rear plate.

10. The apparatus according to claim 9, further comprising first, second, third and fourth insulating means for insulating the upper lid from the gas distributing plate, wherein the first insulating means is formed on the tipper portion of each of the plurality of first screw in each of the plurality of insertion holes, the second insulating means is formed in an upper portion of each of the plurality of first through holes, the third insulating means is formed in a lower portion of each of the plurality of first through holes, and the fourth insulating means is formed between the second flange and the rear plate.

11. The apparatus according to claim 9, wherein the first insulating means includes a first step portion at a lower circumference portion thereof, the second insulating means includes a second step portion at an upper circumference portion thereof and a third step portion at a lower circumference portion thereof and the third insulating means 204 includes a fourth step portion 216 at an upper circumference portion thereof, and wherein the first step portion is inserted into the second step portion and the third step portion is inserted into the fourth step portion.

12. The apparatus according to claim 3, wherein each of the plurality of first screws includes a first screw thread on an outer surface of a lower portion thereof, and each of the plurality of screw holes includes a second screw thread on an inner surface thereof.

13. The apparatus according to claim 12, wherein a distance between the upper lid and the gas distributing plate is controllable by a coupling degree of the plurality of first screws and the plurality of screw holes.

14. The apparatus according to claim 3, further comprising a baffle between the rear plate and the gas distributing plate, wherein the baffle includes a plurality of third through holes for the plurality of first screws.

15. The apparatus according to claim 1, further comprising a gas inlet connected to the rear plate, a gas outlet connected the chamber, a matcher connected to the rear plate and a radio frequency power supply connected to the matcher.
